(19) United States
(12) Patent Application Publication
(10) Pub. No.: US 2012/0326117 A1
(43) Pub. Date: Dec. 27, 2012

(54) SEMICONDUCTOR LIGHT EMMITING DEVICE

(75) Inventors: Akira TANAKA, Kanagawa-ken (JP); Yoko MOTOJIMA, Kanagawa-ken (JP)

(73) Assignee: Kabushiki Kaisha Toshiba, Tokyo (JP)

(21) Appl. No.: 13/399,535

(22) Filed: Feb. 17, 2012

(30) Foreign Application Priority Data
Jun. 24, 2011 (JP) P2011-140245

(51) Int. Cl. H01L 33/04; H01L 33/62

(52) U.S. Cl. 257/13; 257/99; 257/E33.005; 257/E33.064

(57) ABSTRACT

According to one embodiment, in a semiconductor light emitting device, a semiconductor laminated body is made by laminating a first semiconductor layer of a first conductivity type having a first sheet resistance, a light emitting layer, and a second semiconductor layer of a second conductivity type and includes a cutout unit formed at an end side and an indentation unit extending from the cutout unit in a first direction toward the other end side and branching or bending in a second direction substantially perpendicular to the first direction as well as bending or branching in a direction opposite to the second direction. A transparent conductive film is formed on the semiconductor laminated body and has a second sheet resistance less than the first sheet resistance. A first thin wire electrode is formed along the indentation unit. A second thin wire electrode is formed on the transparent conductive film.

### CROSS REFERENCE TO RELATED APPLICATION

This application is based upon and claims the benefit of priority from the prior Japanese Patent Application No. 2011-140245, filed Jun. 24, 2011, the entire contents of which are incorporated herein by reference.

### FIELD

Embodiments described herein relate generally to a semiconductor light emitting device.

### BACKGROUND

In the past, there is a nitride semiconductor light emitting device including a transparent conductive film formed on a nitride semiconductor laminated body, an upper thin wire electrode formed on the transparent conductive film and a lower thin wire electrode formed in an exposed portion made by exposing a lower portion of the nitride semiconductor laminated body. The lower thin wire electrode is formed to correspond to the upper thin wire electrode on the exposed portion. The nitride semiconductor light emitting device is configured to uniformize distribution of a current flowing through the nitride semiconductor laminated body and allow efficient extraction of light.

The reason why a transparent conductive film is used is that, since a nitride semiconductor is a material having a relatively low conductivity, a transparent conductive film improves a spread of current in a nitride semiconductor laminated body, and prevents emitted light from being blocked by an electrode material.

The reason why an upper thin wire electrode and a lower thin wire electrode are used is as follows. Light absorption in a transparent electrode cannot be disregarded, and the thickness of the transparent electrode is limited. Accordingly, the upper thin wire electrode and the lower thin wire electrode make the spread of current less difficult as the size of semiconductor light emitting device increases.

In the nitride semiconductor light emitting device, carriers injected from the upper thin wire electrode are spread in the transparent conductive film, and are recombined with carriers injected from the lower thin wire electrode in the light emitting layer. As a result, uniform light emission is obtained in a large light emitting region.

However, as the more the current is spread, the more the carrier density decreases, which in turn increases the ratio of nonradiative recombination, resulting in a problem of reducing the light emission efficiency itself. When a passed current which passes through the nitride semiconductor laminated body is increased, the carrier density can be increased. However, there is a problem in that the light emission efficiency does not necessarily improve due to heat generation caused by voltage drop and the like.

### BRIEF DESCRIPTION OF THE DRAWINGS

FIGS. 1A and 1B are views illustrating a semiconductor light emitting device according to a first embodiment;

FIGS. 2A to 2D are views illustrating a current distribution of the semiconductor light emitting device in comparison with a current distribution of a comparative example according to the first embodiment;

FIGS. 3A and 3B are views illustrating the characteristic of the semiconductor light emitting device in comparison with the characteristic of the comparative example according to the first embodiment;

FIGS. 4A and 4B are views illustrating the semiconductor light emitting device of the comparative example according to the first embodiment;

FIGS. 5A to 6C are cross-sectional views illustrating the steps of manufacturing the semiconductor light emitting device in sequential order according to the first embodiment;

FIG. 7 is a top view illustrating another semiconductor light emitting device according to the first embodiment;

FIG. 8 is a top view illustrating another semiconductor light emitting device according to the first embodiment;

FIG. 9 is a top view illustrating a semiconductor light emitting device according to a second embodiment;

FIGS. 10A and 10B are views illustrating the characteristic of the semiconductor light emitting device in comparison with the characteristic of the comparative example according to the second embodiment;

FIG. 11 is a top view illustrating another semiconductor light emitting device according to the second embodiment;

FIGS. 12A and 12B are views illustrating another semiconductor light emitting device according to the second embodiment;

FIGS. 13A to 13C are cross-sectional views illustrating main portions of the steps of manufacturing another semiconductor light emitting device in sequential order according to the second embodiment;

FIG. 14 is a top view illustrating another semiconductor light emitting device according to the second embodiment;

FIG. 15 is a top view illustrating a semiconductor light emitting device according to a third embodiment;

FIG. 16 is a top view illustrating another semiconductor light emitting device according to the third embodiment;

FIG. 17 is a top view illustrating a semiconductor light emitting device according to a fourth embodiment;

FIG. 18 is a top view illustrating another semiconductor light emitting device according to the fourth embodiment;

FIG. 19 is a top view illustrating a semiconductor light emitting device according to a fifth embodiment;

FIGS. 20A and 20B are views illustrating a semiconductor light emitting device according to a sixth embodiment;

FIGS. 21A to 21C are cross-sectional views illustrating main portions of the steps of manufacturing another semiconductor light emitting device in sequential order according to the sixth embodiment;

### DETAILED DESCRIPTION

According to one embodiment, in a semiconductor light emitting device, a semiconductor laminated body is made by laminating, in order, a first semiconductor layer of a first conductivity type having a first sheet resistance, a light emitting layer, and a second semiconductor layer of a second conductivity type. The semiconductor laminated body includes a cutout unit formed at an end side so as to expose a portion of the first semiconductor layer. The semiconductor laminated body includes an indentation unit extending from the cutout unit in a first direction toward the other end side and branching or bending in a second direction substantially perpendicular to the first direction as well as bending or branching in a direction opposite to the second direction. A transparent conductive film is formed on the semiconductor laminated body. The transparent conductive film has transparency to light emitted from the light emitting layer and has a second sheet resistance less than the first sheet resistance. A first thin wire electrode is formed on the first semiconductor layer. The first thin wire electrode extends from a first pad electrode formed in the cutout unit along the indentation unit. A second thin wire electrode is formed on the transparent conductive film. The second thin wire electrode extends from a second pad electrode formed at the other end side in the second direction as well as in a direction opposite to the second direction and bends and extends in a direction opposite to the first direction.

Hereinafter, embodiments will be described with reference to the drawings. In the drawings, same reference characters denote the same or similar portions.

### First Embodiment

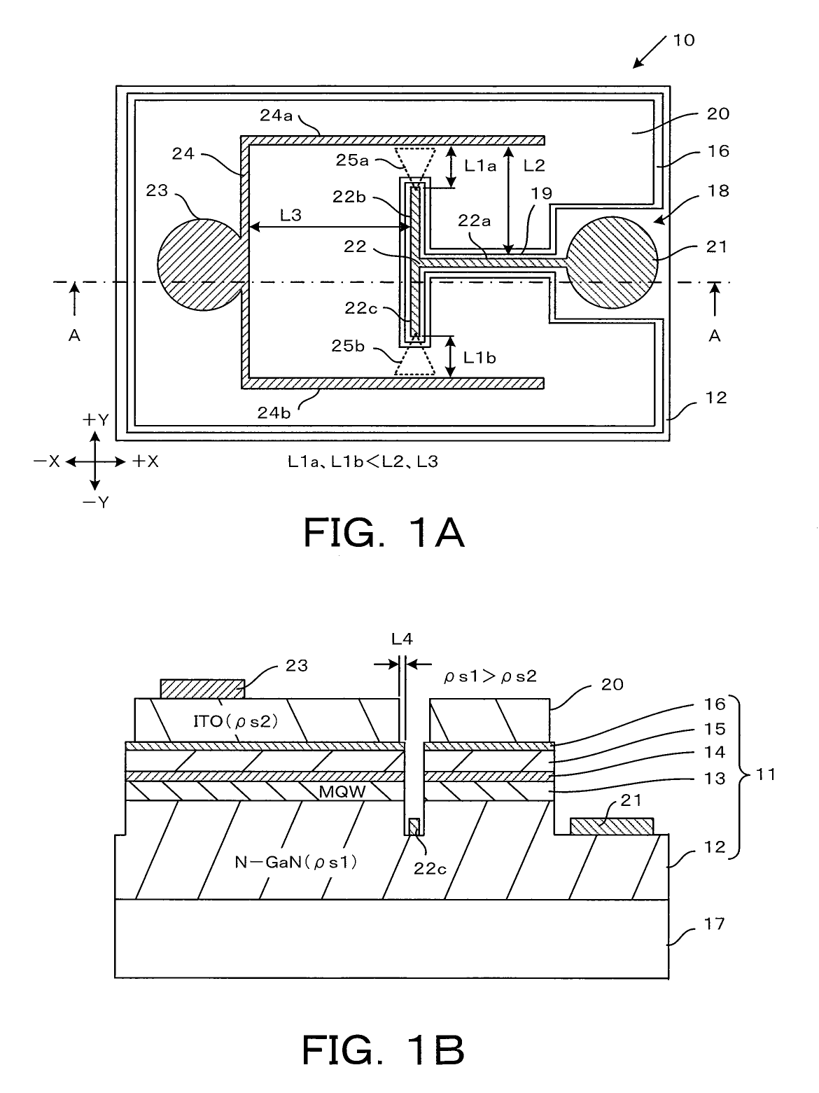

A semiconductor light emitting device of a first embodiment will be described with reference to FIGS. 1A and 1B. FIGS. 1A and 1B are views illustrating the semiconductor light emitting device of the first embodiment. FIG. 1A is a top view illustrating the semiconductor light emitting device. FIG. 1B is a cross-sectional view taken along line A-A of FIG. 1A as seen in an arrow direction.

As shown in FIGS. 1A and 1B, in the semiconductor light emitting device 10 of the first embodiment, a semiconductor laminated body 11 is a nitride semiconductor laminated body having a multi-layer structure made by laminating, in order, an N-type GaN clad layer 12, i.e., a first semiconductor layer of a first conductivity type, a light emitting layer 13, a P-type AlGaN overflow prevention layer 14, i.e., a second semiconductor layer of a second conductivity type, a P-type GaN clad layer 15, and a P-type GaN contact layer 16.

The semiconductor laminated body 11 is formed on a substrate 17 such as a sapphire substrate, which is transparent to the light emitted by the light emitting layer 13.

The semiconductor laminated body 11 includes a cutout unit 18 and an indentation unit 19. The cutout unit 18 is made by cutting out one end side in a rectangular shape so that a portion of the N-type GaN clad layer 12 is exposed. The indentation unit 19 extends in a first direction from the cutout unit 18 to the other end side (−X direction in the figure), and branches to a second direction substantially perpendicular to the first direction (+Y direction in the figure) and a direction opposite to the second direction (−Y direction in the figure).

A transparent conductive film 20 such as an ITO (Indium Tin Oxide) film having a thickness of 0.1 to 0.2 μm, which is transparent to the light emitted from the light emitting layer 13, is formed on the P-type GaN contact layer 16 of the semiconductor laminated body 11.

In the transparent conductive film 20, a current is spread to the periphery of the semiconductor light emitting device 10. A thicker ITO film is preferred in terms of spreading the current. On the other hand, since the ITO film slightly absorbs light, the thinner ITO film is preferred in terms of extracting light. Hereinafter, the transparent conductive film is also referred to as ITO film.

The transparent conductive film 20 is formed inside of the edge of the P-type GaN contact layer 16 by a distance L4, 10 μm, for example, in order to alleviate a surface current flowing along a side surface of the semiconductor laminated body 11. The distance L4 is preferably equal to or more than 10 times the diffusion length (in the order of 0.1 μm) of minority carriers injected into the light emitting layer 13.

A first pad electrode 21 is formed on the N-type GaN clad layer 12 in the cutout unit 18. A first thin wire electrode 22 is formed from the first pad electrode 21 along the indentation unit 19.

The first pad electrode 21 includes a first wire 22a, a second wire 22b, and a third wire 22c. The first wire 22a extends from the first pad electrode 21 in −X direction. The second wire 22b is branched from the first wire 22a in +Y direction. The third wire 22c is branched from the first wire 22a in −Y direction.

The first pad electrode 21 and the first thin wire electrode 22 are laminated films including titanium (Ti)/platinum (pt)/gold (Au), for example.

A second pad electrode 23 is formed on the transparent conductive film 20 at the other end side. A second thin wire electrode 24 is formed from the second pad electrode 23 to enclose the first thin wire electrode 22. The second thin wire electrode 24 includes a fourth wire 24a and a fifth wire 24b extending from the second pad electrode 23 in +/−Y directions and bending and extending in +X direction.

The second pad electrode 23 and the second thin wire electrode 24 are gold (Au) or aluminum (Al) film, for example.

A first distance between portions where the first thin wire electrode 22 and the second thin wire electrode 24 face each other in a substantially perpendicular direction in top view is set at a distance shorter than a second distance between portions where the first thin wire electrode 22 and the second thin wire electrode 24 face each other in a substantially parallel direction.

The second wire 22b is disposed in such positional relationship that the second wire 22b is substantially perpendicular to the fourth wire 24a, and the third wire 22c is disposed in such positional relationship that the third wire 22c is substantially perpendicular to the fifth wire 24b. The first distance between the second wire 22b and the fourth wire 24a is set at L1a, and the first distance between the third wire 22c and the fifth wire 24b is set at L1b.

Where the second distance between the first wire 22a and the fourth wire 24a facing each other in parallel is denoted as L2, and the second distance between the second wire 22b and the fourth wire 24a facing each other in parallel is denoted as L3, the following relationships are satisfied: L1a<L2, L3 and L1b<L2, L3.

When the size of the semiconductor light emitting device 10 is 450 μm×450 μm, the first distances L1a, L1b are set at approximately 30 μm to 60 μm, for example.

Since the N-type GaN clad layer 12 has an impurity concentration of approximately 2E18 cm⁻³ and a mobility of approximately 300 to 400 cm²/V·s, for example, the resistivity is 8E-3 to 1E-2 Ωcm. When the thickness of the N-type GaN clad layer 12 is 4 μm, a first sheet resistance ρs1 of the N-type GaN clad layer 12 is 20 to 25Ω/.

The resistivity of the transparent conductive film 20 varies in accordance with processes and conditions, but can be 2E-4 Ωcm. A second sheet resistance ρs2 of the transparent conductive film 20 becomes 12Ω/ or less even when the thickness is 0.2 μm or less at which sufficient transmittance 80% or more, for example, can be obtained.

Therefore, it is possible to set the second sheet resistance ρs2 of the transparent conductive film 20 less than the first sheet resistance ρs1 of the N-type GaN clad layer 12 while maintaining sufficient transmittance.

Although the semiconductor laminated body 11 is well-known, the semiconductor laminated body 11 will be hereinafter described briefly. The N-type GaN clad layer 12 also serves as an underlying single crystal layer for epitaxially growing the light emitting layer 13 to P-type GaN contact layer 16. The N-type GaN clad layer 12 is formed on the substrate 17 to be as thick as approximately 2 to 5 μm, for example.

The light emitting layer 13 is a Multiple Quantum Well (MQW) made by alternately laminating InGaN well layers and InGaN barrier layers, for example.

The InGaN barrier layer has a thickness of 10 nm and an In composition ratio of 0.05, for example. The InGaN well layer has a thickness of 2.5 nm and an In composition ratio of 0.2, for example. Eight sets of InGaN well layers and InGaN barrier layers are formed, for example.

The P-type AlGaN overflow prevention layer 14 has a thickness of 10 nm and an Al composition ratio of 0.15, for example. The P-type GaN clad layer 15 has a thickness of 40 nm, for example. The band gap of the P-type AlGaN overflow prevention layer 14 is larger than the band gap of the P-type GaN clad layer 15. The P-type GaN contact layer 16 has a thickness of 5 nm, for example.

By applying a voltage between the first pad electrode 21 and the second pad electrode 23, the carriers injected into the light emitting layer 13 are recombined, and light having a peak wavelength of approximately 450 nm is emitted, for example.

The semiconductor light emitting device 10 of the first embodiment is configured such that the current densities between the second wire 22b and the fourth wire 24a and between the third wire 22c and the fifth wire 24b are made higher than the other portions, and regions 25a, 25b of which carrier densities are higher are generated locally within the light emitting layer 13.

Further, the semiconductor light emitting device 10 of the first embodiment is configured to easily obtain a current density distribution in accordance with the pattern of the first thin wire electrode 22 by setting the second sheet resistance ρs2 less than the first sheet resistance ρs1 (ρs1>ρs2).

The light emission efficiency of a semiconductor light emitting device is determined by a balance between a radiative recombination lifetime of electron-hole pair and a nonradiative recombination lifetime of electron-hole pair.

The nonradiative recombination includes Auger Recombination, which is proportional to the cube of the carrier density, and Shockley-Read-Hall (SRH) Recombination, which is proportional to the carrier density. In a case of a low current with a low carrier density, and in a case of a semiconductor in which Auger recombination is less likely to occur, the effect of the SRH recombination is great.

In such case, the light emission efficiency of the semiconductor light emitting device is mainly dominated by a radiative recombination probability which is proportional to the square of the carrier density and an SRH nonradiative recombination probability.

When condensation and rarefaction of carrier densities are provided within the light emitting layer 13, the radiative recombination probability is sufficiently larger than the SRH nonradiative recombination probability in the region where the carrier density is high, and the light emission efficiency becomes relatively higher.

On the other hand, in the region where the carrier density is low, the difference between the radiative recombination probability and the SRH nonradiative recombination probability becomes smaller, and the light emission efficiency becomes relatively lower.

Therefore, by optimizing the ratio between the regions where the carrier density is high and the regions where the carrier density is low and the in-plane distribution of the regions where the carrier density is high and the regions where the carrier density is low, the overall light emission efficiency can be improved. As compared with a case where the current distribution flowing in the light emitting layer 13 is simply uniformized, a high light emission efficiency can be obtained.

The current spreads substantially along the transparent conductive film 20. The spread of the current along the P-type layers such as the P-type GaN clad layer 15 and the P-type GaN contact layer 16 can be disregarded. As a result, a current flows from the P-type GaN contact layer 16 to the light emitting layer 13 in a direction perpendicular to the substrate 17, and a current density distribution in accordance with the pattern of the first thin wire electrode 22 can be obtained.

Therefore, the ratio between the regions where the carrier density is high and the regions where the carrier density is low and the in-plane distribution of the regions where the carrier density is high and the regions where the carrier density is low can be easily optimized.

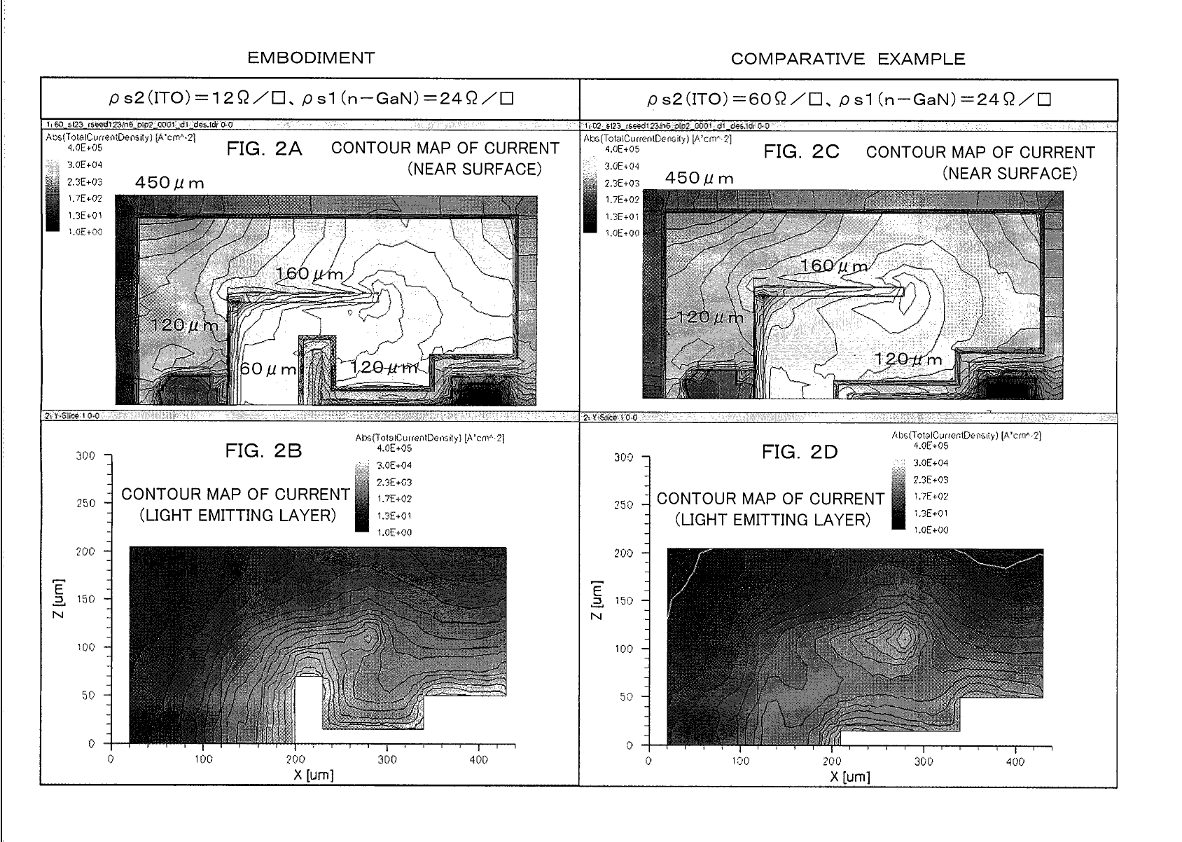

FIGS. 2A to 2D are views illustrating a simulation result of current distributions of the semiconductor light emitting device as compared with a comparative example. FIGS. 2A and 2B are views illustrating current distributions of the light emitting layer and in proximity to the surface of the semiconductor light emitting device of the first embodiment. FIGS. 2C and 2D are views illustrating current distributions of a light emitting layer and in proximity to a surface of a semiconductor light emitting device of the comparative example.

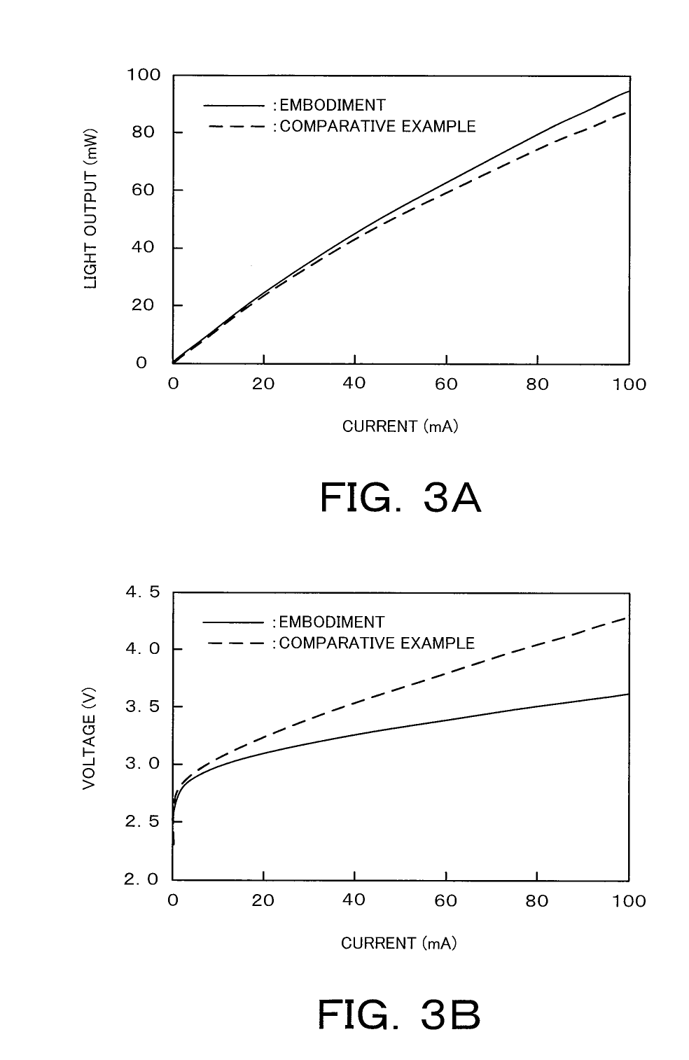

FIGS. 3A and 3B are views illustrating a result obtained by measuring the characteristic of the semiconductor light emitting device as compared with the comparative example. FIG. 3A is a view illustrating relationship between a passed current and a light output. FIG. 3B is a view illustrating relationship between a passed current and a voltage drop. In FIGS. 3A and 3B, a solid line represents the characteristic of the semiconductor light emitting device of the first embodiment, and a broken line represents the characteristic of the semiconductor light emitting device of the comparative example.

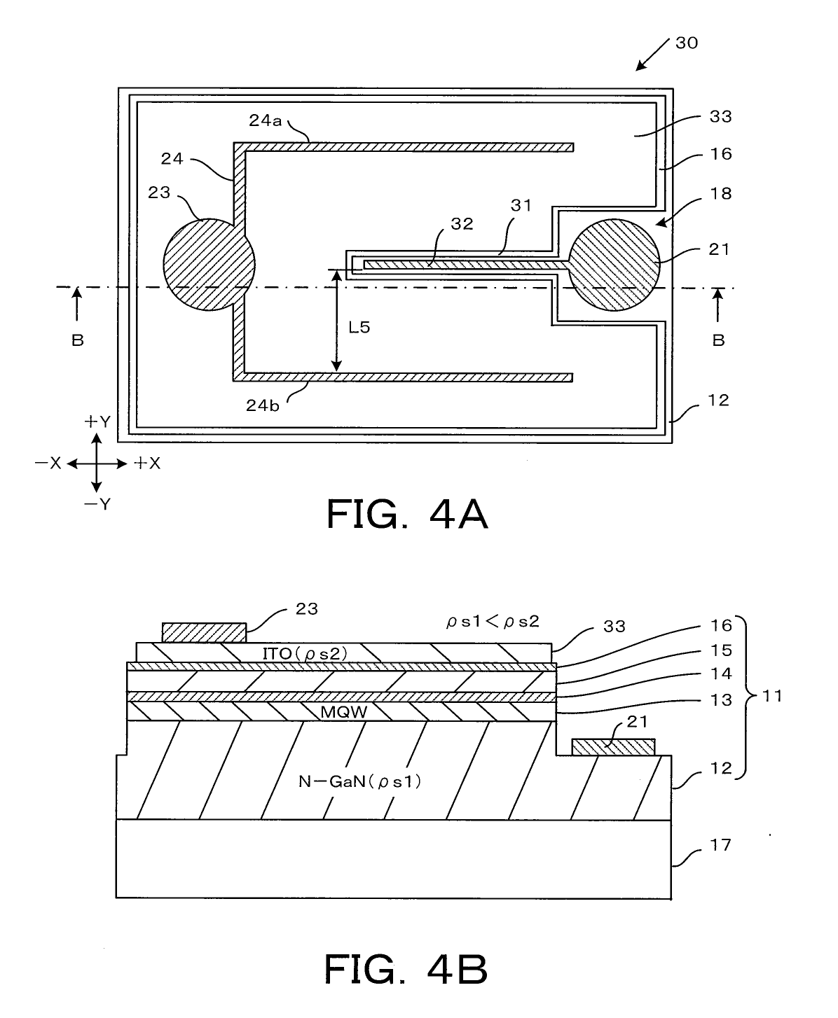

FIGS. 4A and 4B are views illustrating the semiconductor light emitting device of the comparative example. FIG. 4A is a top view. FIG. 4B is a cross-sectional view taken along line B-B of FIG. 4 as seen in an arrow direction. The semiconductor light emitting device of the comparative example is a semiconductor light emitting device having a transparent conductive film with a higher sheet resistance than the sheet resistance of the N-type GaN clad layer.

As shown in FIGS. 4A and 4B, the semiconductor light emitting device 30 according to the comparative example has an indentation unit 31 extending from a cutout unit 18 in −X direction. A first thin wire electrode 32 is formed from the first pad electrode 21 formed in the cutout unit 18 along the indentation unit 31. The second thin wire electrode 24 extends in to a position close to the first pad electrode 21 so as to sandwich the first thin wire electrode 32.

The simulation was performed using finite element method with regard to an upper half of the top view of FIG. 1A using symmetrical property. The simulation conditions are as follows.

The semiconductor light emitting devices 10, 30 are the same in that the size of the semiconductor light emitting devices 10, 30 is 450 μm×450 μm, the lengths of the second thin wire electrode 24 in X/Y directions are 160 μm/240 μm, the first sheet resistance ρs1 of the N-type GaN clad layer 12 is 24Ω/, and the applied voltage is 4.5 V.

In the semiconductor light emitting device 10 of the first embodiment, the lengths of the first thin wire electrode 22 in X, Y directions are both 120 μm, and the first distances L1a, L1b between the second wire 22b and the fourth wire 24a and between the third wire 22c and the fifth wire 24b are both 60 μm. The second sheet resistance ρs2 of the transparent conductive film 20 is 12Ω/. The second distance L3 between the first wire 22b and the fourth wire 24a facing in parallel is 100 μm.

In the semiconductor light emitting device 30 of the comparative example, the length of the first thin wire electrode 32 in the X direction is 120 μm, the distance L5 between the second thin wire electrode 24 and the first thin wire electrode 32 in parallel is 120 μm. The second sheet resistance ρs2 of the transparent conductive film 33 is 60Ω/.

As shown in FIGS. 2A and 2C, in the semiconductor light emitting device 10 of the first the embodiment, a larger current flows in proximity to the surface, i.e., in the transparent conductive film 20, mainly, as compared with the semiconductor light emitting device 30 of the comparative example.

As shown in FIGS. 2B and 2D, it is understood that, in the semiconductor light emitting device 10 of the first embodiment, the current distribution in the light emitting layer 13 is concentrated in proximity to the second wire 22b of the first thin wire electrode 22 as compared with the semiconductor light emitting device 30 of the comparative example. This reflects the current density distribution in proximity to the surface as shown in FIGS. 2A and 2C.

As shown in FIG. 3A, in the semiconductor light emitting device 10 of the first embodiment, the following result was obtained. With any current value, light output increased as compared with the semiconductor light emitting device 30 of the comparative example. From the above fact, it was confirmed that the semiconductor light emitting device 10 of the first embodiment provided an improved light emission efficiency higher than the light emission efficiency obtained from the semiconductor light emitting device 30 of the comparative example.

As shown in FIG. 3B, in the semiconductor light emitting device 10 of the first embodiment, the following result was obtained. With any current value, the voltage dropped less as compared with the semiconductor light emitting device 30 of the comparative example. This was because the second sheet resistance ρs2 of the transparent conductive film 20 was less than the second sheet resistance ρs2 of the transparent conductive film 33, and the first distances L1a, L1b were shorter than the distance L5, which reduced the voltage drop in the transparent conductive film 20.

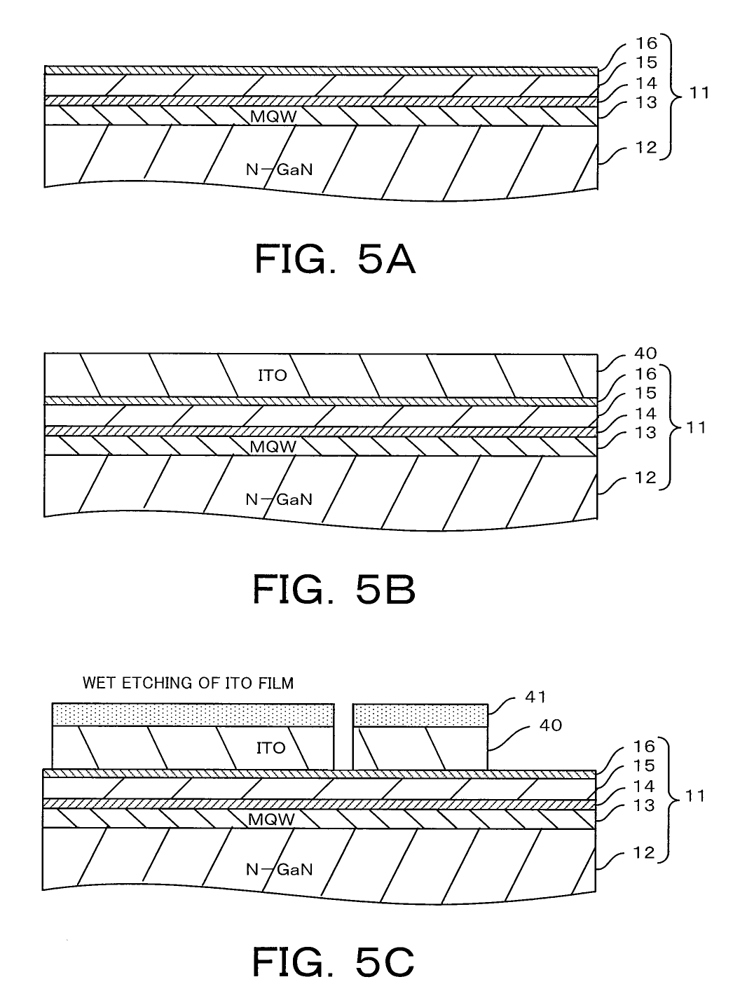

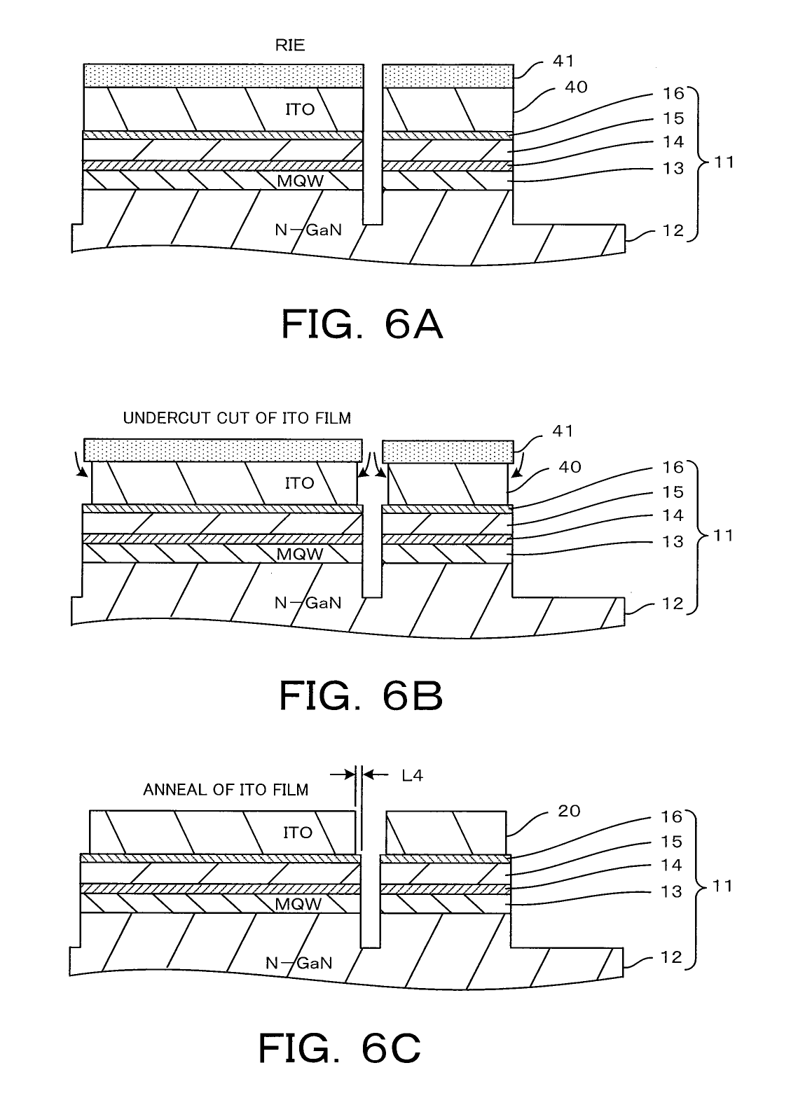

Next, a method of manufacturing the semiconductor light emitting device 10 will be explained. FIGS. 5A to 6C are cross-sectional views illustrating the steps of manufacturing the semiconductor light emitting device 10 in the sequential order.

As shown in FIG. 5A, the N-type GaN clad layer 12, the light emitting layer 13, the P-type AlGaN overflow prevention layer 14, the P-type GaN clad layer 15 and the P-type GaN contact layer 16 are epitaxially grown on the substrate 17 (not shown) for epitaxial growth in the order by a MOCVD (metal organic chemical vapor deposition) method so as to form the semiconductor laminated body 11.

The method of forming the semiconductor laminated body 11 is well known, but briefly described below. As a preliminary treatment, a sapphire substrate with a C plane of a plane direction as the substrate 17 is subjected to organic cleaning and acid cleaning, for example. The resultant sapphire substrate is contained in a reaction chamber of the MOCVD system. Thereafter, the temperature of the sapphire substrate is raised to 1100° C., for example, by high-frequency heating in a normal-pressure atmosphere of a mixed gas of a nitrogen (N₂) gas and a hydrogen (H₂) gas. Thereby, the surface of the sapphire substrate is etched in gas phase, and a natural oxide film formed on the surface of the sapphire substrate is removed.

The N-type GaN layer 12 with a thickness of 4 μm is formed by using the mixed gas of the N₂ gas and the H₂ gas as a carrier gas while supplying an ammonium (NH₃) gas and a trimethyl gallium (TMG) gas, for example, as process gases, and supplying a silane (SiH₄) gas, for example, as the n-type dopant.

The temperature of the substrate 17 is decreased to and kept at 800° C. which is lower than 1100° C., for example, while continuing supplying the NH₃ gas with the supply of the TMG gas and the SiH₄ gas stopped.

The InGaN barrier layer with a thickness of 10 nm, in which the In composition ratio is 0.05, is formed by using the N₂ gas as the carrier gas while supplying the NH₃ gas, the TMG gas and a trimethyl indium (TMI) gas, for example, as the process gases. After that, the InGaN well layer with a thickness of 2.5 nm, in which the In composition ratio is 0.2, is formed by increasing the supply of the TMI gas.

The forming of the InGaN barrier layer and the forming of the InGaN well layer are alternately repeated 8 times, for example, while increasing or decreasing the supply of the TMI gas. Thereby, the MQW layer is obtained.

The undoped GaN cap layer with a thickness of 5 nm (not shown) is formed while continuing supplying the TMG gas and the NH₃ gas with the supply of TMI stopped.

The temperature of the substrate 17 is raised to and kept at 1030° C., for example, which is higher than 800° C., in the N₂ gas atmosphere while continuing supplying the NH₃ gas with the supply of the TMG gas stopped.

the p-type AlGaN overflow prevention layer 14 with a thickness of 10 nm, in which the Al composition ratio is 0.15 and the concentration of Mg is approximately 1E8 cm⁻³, is formed by using the mixed gas of the N₂ gas and the H₂ gas as the carrier gas while supplying: the NH₃ gas, the TMG gas and a trimethyl aluminum (TMA) gas as the process gases; and a bis(cyclopentadienyl) magnesium (Cp2Mg) gas as the p-type dopant.

The p-type GaN clad layer 15 with a thickness of approximately 40 nm, in which the concentration of Mg is approximately 1E20 cm⁻³, is formed while continuing supplying the TMG gas, the NH₃ gas and the Cp2Mg gas with the supply of the TMA gas stopped.

The p-type GaN contact layer 16 with a thickness of approximately 10 nm, in which the concentration of Mg is approximately 1E21 cm⁻³, is formed while supplying an increased amount of Cp2Mg.

The temperature of the substrate 17 is lowered naturally with the supply of only the carrier gas continued while continuing supplying the NH₃ gas with the supply of the TMG gas stopped. The supplying of the NH₃ gas is continued until the temperature of the substrate 17 reaches 500° C. Thereby, the semiconductor laminated body 11 is formed on the e substrate 17 and the P-type GaN contact layer 16 is located in the top surface.

As shown in FIG. 5B, an ITO film 40 having a thickness of approximately 0.2 μm is formed on a P-type GaN contact layer 16 by sputtering method, for example.

In general, it is known that, when an ITO film is formed by sputtering method and the like, an ITO film can be obtained that includes amorphous ITO and crystalline ITO in a mixed manner depending on the substrate temperature during deposition, the plasma density, the oxygen partial pressure, and the like.

In the substrate temperature, for example, the crystallization temperature of ITO is around 150° C. to 200° C. When the substrate temperature is around the crystallization temperature, an ITO film in which amorphous ITO and crystalline ITO are mixed can be obtained.

As shown in FIG. 5C, a resist film 41 having openings corresponding to the cutout unit 18 and the indentation unit 19 is formed on the ITO film 40 by photolithographic method. Using the resist film 41 as a mask, the ITO film 40 is wet-etched with mixed acid including hydrochloric acid and nitric acid, for example. The etching process is performed until both of the crystallization ITO and the amorphous ITO are removed.

The etching speed of the crystalline ITO is slower than the etching speed of the amorphous ITO. The etching speed of the crystalline ITO is about 50 to 100 nm/min, for example. The etching speed of the amorphous ITO is about 100 to 500 nm/min, for example.

At this occasion, the ITO film 40 is side-etched by approximately 1 μm, for example. On the other hand, since the resist film 41 is not etched, the resist film 41 does not become thin, and substantially maintains the initial thickness.

It should be noted that since the crystalline ITO is likely to remain as residue, it is preferable to physically remove the crystalline ITO by performing etching by applying ultrasonic wave or performing ultrasonic cleaning after etching.

As shown in FIG. 6A, while the resist film 41 is remained, the layers from the P-type GaN contact layer 16 to the upper portion of the N-type GaN clad layer 12 are anisotropically etched using the resist film 41 as the mask by RIE method using a gas of chlorine system, and a portion of the N-type GaN clad layer 12 is exposed.

As shown in FIG. 6B, while the resist film 41 is remained, the ITO film 40 is wet-etched again using the resist film 41 as the mask. The ITO film 40 is undercut, and the ITO film 40 is backed to the inside by a distance L4 from the edge of the P-type GaN contact layer 16.

After the resist film 41 is removed using asher, for example, heat treatment is performed on the ITO film 40 in order to expedite crystallization of the ITO film 40 and enhance the conductivity of the ITO film 40 as shown in FIG. 6C. It is appropriate to perform the heat treatment in nitrogen atmosphere or mixed atmosphere of nitrogen and oxygen, for example, at a temperature of approximately 400° C. to 750° C. for a time of approximately 1 to 20 minutes.

At this stage, the ITO film 40 becomes the transparent conductive film 20 as shown in FIG. 1. The ITO film 20 having a thickness of approximately 0.2 μm absorbs much light, but the sheet resistance is generally lower than the sheet resistance of the N-type GaN clad layer 12.

Using a well-known method, the first pad electrode 21 and the first thin wire electrode 22 are formed. The first pad electrode 21 is formed on the N-type GaN layer 12 in the cutout unit 18. The first thin wire electrode 22 extends from the first pad electrode 21 along the indentation unit 19.

The second pad electrode 23 and the second thin wire electrode 24 are formed. The second pad electrode 23 is formed on the transparent conductive film 20 at the other end side. The second thin wire electrode 24 extends from the second pad electrode 23 in +/−Y directions and bending and extending in +X direction. As a result, the semiconductor light emitting device 10 shown in FIGS. 1A and 1B is obtained.

As described above, in the semiconductor light emitting device 10 of the first embodiment, the second wire 22b and the fourth wire 24a are disposed substantially perpendicular to each other, and the third wire 22c and the fifth wire 24b are arranged substantially perpendicular to each other, so that the second wire 22b and the fourth wire 24a are as close as the first distance L1a, and the third wire 22c and the fifth wire 24b are as close as the first distance L1b.

Further, the second sheet resistance ρs2 of the transparent conductive film 20 is less than the first sheet resistance ρs1 of the N-type GaN clad layer 12 (ρs1>ρs2).

As a result, the current is expanded to the peripheral portion, and the high carrier density regions 25a, 25b are generated locally within the light emitting layer 13. In the high carrier density regions 25a, 25b, the light emission efficiency is higher than the other portions.

Therefore, condensation and rarefaction is provided in the carrier density, and the semiconductor light emitting device having an improved light emission efficiency in whole is obtained. It is easy to optimize the carrier density and the position where the region with high carrier density is formed locally within the light emitting layer 13.

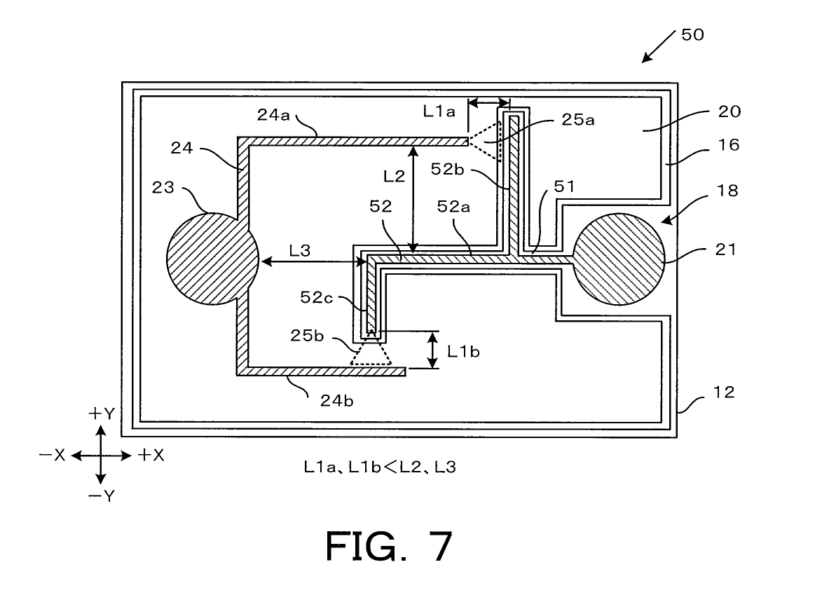

The description of the first embodiment assumes that the first thin wire electrode is branched to +/−Y directions, i.e., a so-called T-shape type. However, other shapes similar to the so-called T-shape type may be employed. FIG. 7 is a top view illustrating another semiconductor light emitting device.

As shown in FIG. 7, in a semiconductor light emitting device 50, an indentation unit 51 is formed. The indentation unit 51 extends from a cutout unit 18 in −X direction, and branches in +Y direction in the middle, and the end of the indentation unit 51 is bent in −Y direction.

A first thin wire electrode 52 is formed along the indentation unit 51. The first thin wire electrode 52 includes a first wire 52a, a second wire 52b, and a third wire 52c. The first wire 52a extends from the first pad electrode 21 in −X direction. The second wire 52b is branched in +Y direction in the middle. The end of the third wire 52c is bent.

In the top view, the second wire 52b and the fourth wire 24a are arranged substantially perpendicular to each other, and the third wire 52c and the fifth wire 24b are arranged substantially perpendicular to each other, so that the second wire 52b and the fourth wire 24a are as close as the first distance L1a, and the third wire 52c and the fifth wire 24b are as close as the first distance L1b.

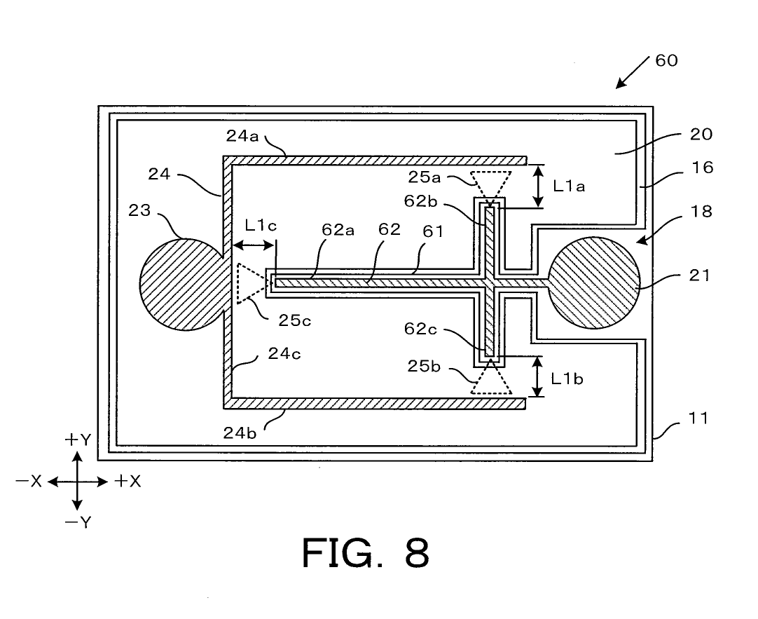

The description of the first embodiment assumes that there are two regions where the carrier densities are high. Further, there may be more than two regions where the carrier densities are high. FIG. 8 is a top view illustrating a semiconductor light emitting device having three regions where the carrier densities are high

As shown in FIG. 8, in a semiconductor light emitting device 60, a so-called cross-shaped indentation unit 61 is formed. The indentation unit 61 extends from a cutout unit 18 in −X direction to a position close to the second pad electrode 23, and branches in +/−Y directions in the middle.

A first thin wire electrode 62 is formed along the indentation unit 61. The first thin wire electrode 62 includes a first wire 62a and second and third wires 62b, 62c. The first wire 62a extends from the first pad electrode 21 in −X direction to a position close to the second pad electrode 23. The second and third wires 62b, 62c branch in +/−Y directions in the middle.

In the top view, the first wire 62a is disposed in a positional relationship such that the first wire 62a is substantially perpendicular to a wire 24c of +/−Y directions of the second thin wire electrode 24, and a distance between the first wire 62a and the wire 24c is L1c.

Therefore, three high carrier density regions 25a, 25b, 25c are formed around the ends of the first to third wires 62a, 62b, 62c of the first thin wire electrode 62. The regions where the carrier densities are high are increased and distributed, so that while the light emission efficiency is maintained, the in-plane light emission intensity can be uniformized.

The second and third wires 62b, 62c branch at the same position in +/−Y directions. Alternatively, the second and third wires 62b, 62c may branch at different positions.

The description of the first embodiment assumes that the substrate 17 is a sapphire substrate. Alternatively, a SiC substrate and a GaN substrate may also be used.

### Second Embodiment

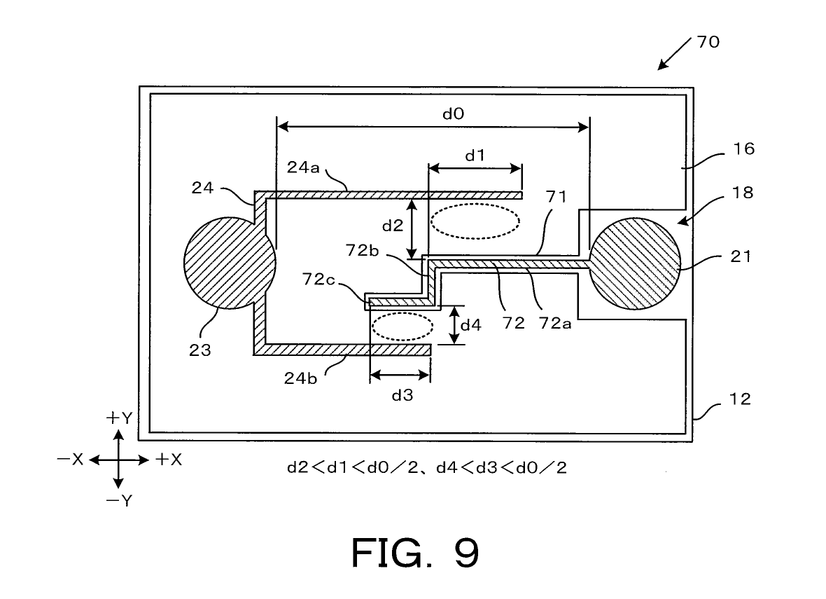

A semiconductor light emitting device of a second embodiment will be described with reference to FIG. 9. FIG. 9 is a top view illustrating the semiconductor light emitting device of the second embodiment. In the second embodiment, the same constituent portions as those of the first embodiment are denoted with the same reference numerals, but the description for the same portions with the same reference numerals is omitted. Only different portions will be hereinafter described.

The embodiment is different from the first embodiment in that the distance between portions of a first thin wire electrode and a second thin wire electrode facing each other in parallel is shorter than the length of portions facing each other in parallel.

As shown in FIG. 9, a semiconductor light emitting device 70 of the second embodiment has an indentation unit 71. The indentation unit 71 extends from a cutout unit 18 in −X direction, bends in −Y direction, and further bends in −X direction.

A first thin wire electrode 72 is formed from the first pad electrode 21 formed on the N-type GaN clad layer 12 in the cutout unit 18, and the first thin wire electrode 72 is formed along the indentation unit 71. The first thin wire electrode 72 includes a first wire 72a, a second wire 72b, and a third wire 72c. The first wire 72a extends from the first pad electrode 21 in −X direction. The second wire 72b is bent from the first thin wire 72a in −Y direction. The third wire 72c is bent from the second wire 72b in −X direction.

In the top view, the first pad electrode 21 and the second pad electrode 23 face each other. The first wire 72a of the first thin wire electrode 72 and the fourth wire 24a of the second thin wire electrode 24 face each other in parallel. The third wire 72c of the first thin wire electrode 72 and the fifth electrode 24b of the second thin wire electrode 24 face each other in parallel.

The distance between the first pad electrode 21 and the second pad electrode 23 is d0. The length of the portions where the first electrode 72a and the fourth wire 24a face each other is d1. The distance of the portions where the first electrode 72a and the fourth wire 24a face each other is d2. The length of the portions where the third wire 82c and the fifth wire 24b face each other is d3. The distance between the portions where the third wire 72c and the fifth wire 24b face each other is d4.

The distance d1 is set at a value less than ½ of d0 and more than d2 (d2<d1<d0/2). The distance d3 is set at a value less than ½ of d0 and more than d4 (d4<d3<d0/2).

Therefore, the current is concentrated with a high degree of controllability, and the increase of the operation voltage can be suppressed. Since the lengths d1, d3 are less than ½ of d0, multiple portions facing each other in parallel can be provided. The first pad electrode 21 and the second pad electrode 23 absorb less light, and the light emission efficiency can be improved.

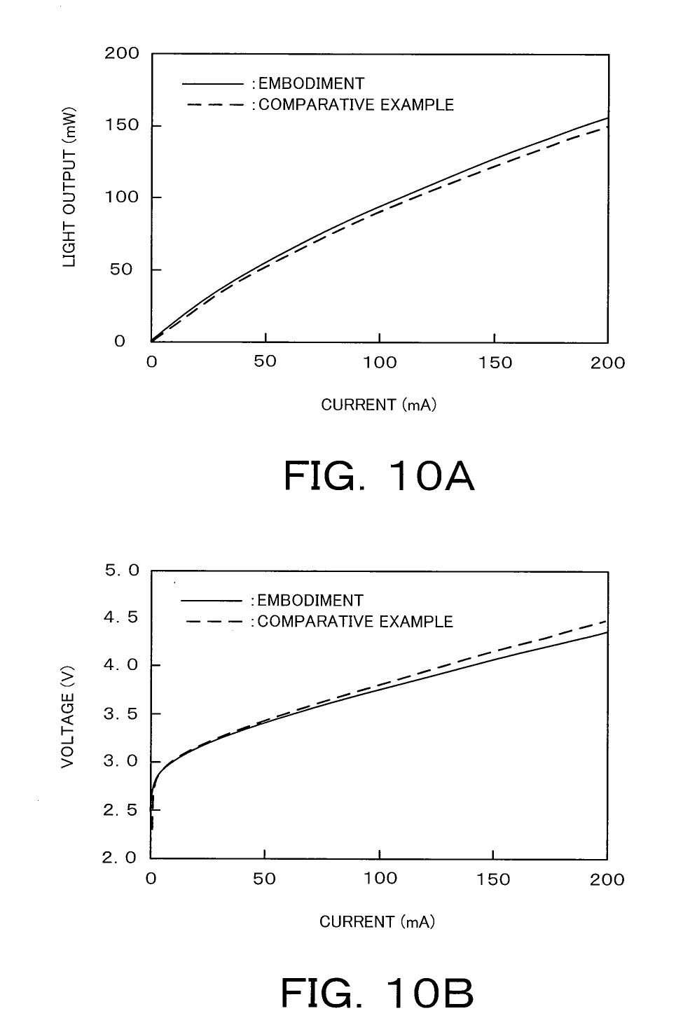

FIGS. 10A and 10B are views illustrating results obtained by measuring the characteristic of the semiconductor light emitting device 70 as compared with the semiconductor light emitting device of the comparative example. FIG. 10A is a view illustrating relationship between a passed current and a light output. FIG. 10B is a view illustrating relationship between a passed current and a voltage drop. In FIGS. 10A and 10B, a solid line represents the characteristic of the semiconductor light emitting device of the second embodiment, and a broken line represents the characteristic of the semiconductor light emitting device of the comparative example.

In this case, the semiconductor light emitting device of the comparative example is a semiconductor light emitting device without the transparent conductive film 33 of the semiconductor light emitting device 30 as shown in FIG. 4.

As shown in FIG. 10A, in the semiconductor light emitting device 70 of the second embodiment, the following result was obtained. With any current value, light output increased as compared with the semiconductor light emitting device of the comparative example. As shown in FIG. 10B, in the semiconductor light emitting device 70 of the second embodiment, the following result was obtained. With any current value, the voltage dropped less as compared with the semiconductor light emitting device of the comparative example.

From the above fact, it was confirmed that the semiconductor light emitting device 70 of the second embodiment provided an improved light emission efficiency higher than the light emission efficiency obtained from the semiconductor light emitting device of the comparative example, and the increase of the operation voltage was suppressed in the semiconductor light emitting device 70 of the second embodiment.

As described above, in the semiconductor light emitting device 70 of the second embodiment, the lengths of the portions where the first thin wire electrode 71 and the second thin wire electrode 24 face each other in parallel (d1, d3) are less than ½ of the distance (d0) between the first, second pad electrodes 21, 23, and the distance between the portions facing each other in parallel (d2, d4) is less than the lengths of the portions facing each other in parallel (d1, d3).

Therefore, there is an advantage in that the current is concentrated with a high degree of controllability, and the increase of the operation voltage can be suppressed.

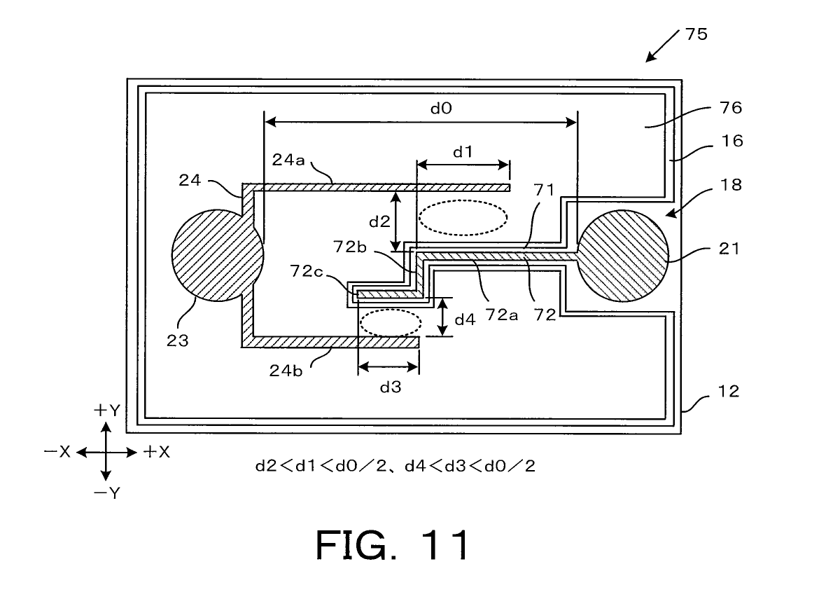

It is possible to provide a transparent conductive film and a current block layer in the semiconductor light emitting device 70. FIG. 11 is a top view illustrating a semiconductor light emitting device having a transparent conductive film formed thereon. As shown in FIG. 11, the semiconductor light emitting device 75 includes the same transparent conductive film 76 as the semiconductor light emitting device 10 shown in FIG. 1.

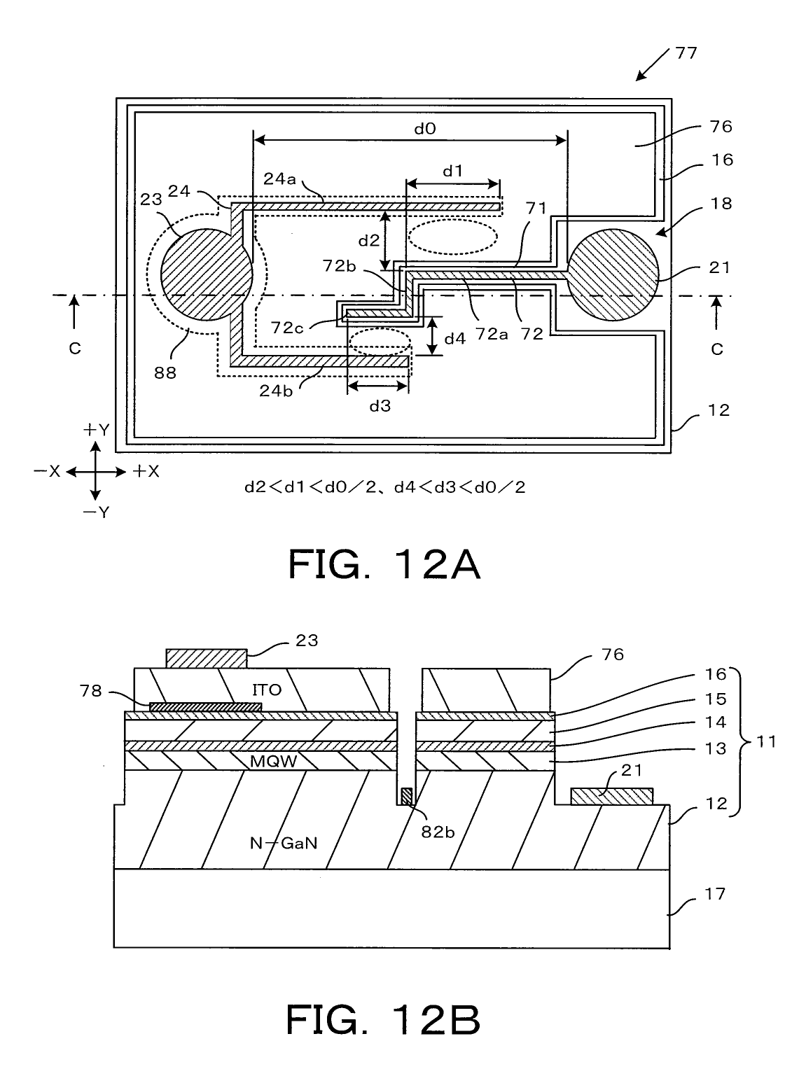

FIGS. 12A and 12B are views illustrating a semiconductor light emitting device having a transparent conductive film and a current block layer. FIG. 12A is a top view of the semiconductor light emitting device. FIG. 12B is a cross-sectional view taken along line C-C of FIG. 12A as seen in an arrow direction.

As shown in FIGS. 12A and 12B, a semiconductor light emitting device 77 includes not only the transparent conductive film 76 but also a current block layer 78, corresponding to the second pad electrode 23 and the second thin wire electrode 24, formed between the P-type GaN contact layer 16 and the transparent conductive film 76.

The current block layer 78 is a silicon oxide film, for example. The current block layer 78 is formed to be one size larger than the second pad electrode 23 and the second thin wire electrode 24.

With the current block layer 78, no current flows immediately under the second pad electrode 23 and the second thin wire electrode 24. The light emission cut off by the second pad electrode 23 and the second thin wire electrode 24 is suppressed in advance.

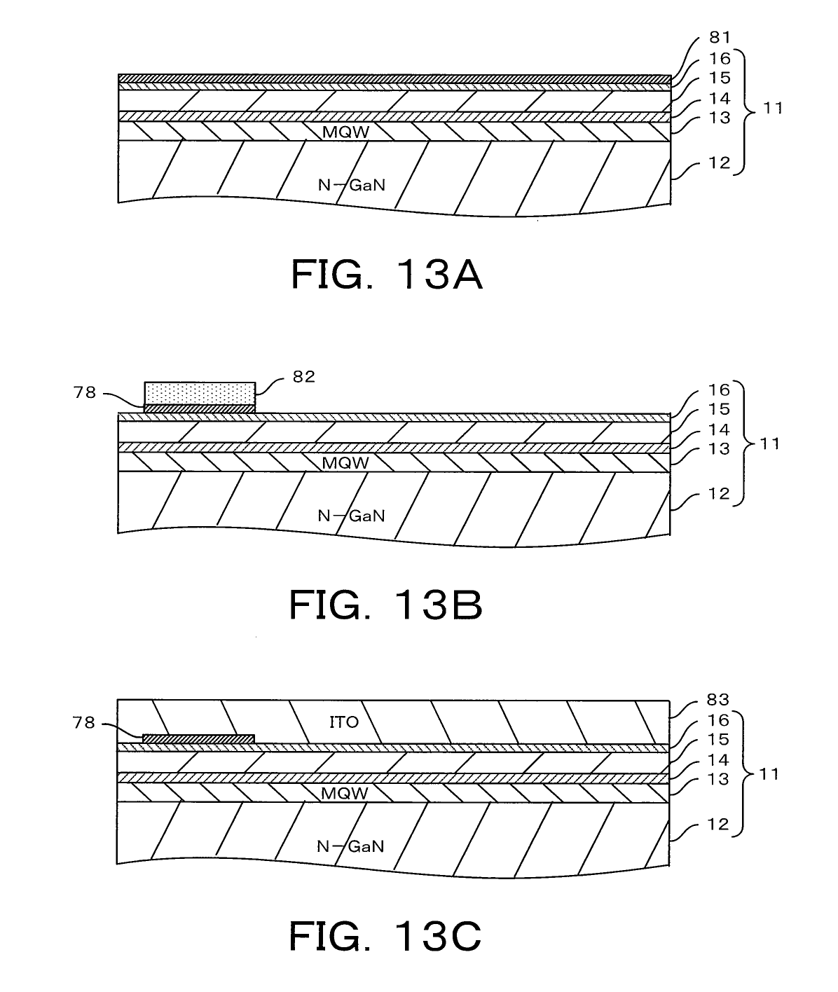

FIGS. 13A to 13C are cross-sectional views illustrating, in order, main portions of the steps of manufacturing the semiconductor light emitting device 77. As shown in FIG. 13A, after the semiconductor laminated body 11 is formed on the substrate 17, for example, a silicon oxide film 81 having a thickness of approximately 100 nm is formed by CVD (Chemical Vapor Deposition) method.

As shown in FIG. 13B, a resist film 82 corresponding to the current block layer 78 is formed by photolithographic method. Using the resist film 82 as a mask, the silicon oxide film 81 is wet-etched. As a result, a current block film 78 is formed.

As shown in FIG. 13C, an ITO film 83 is formed on the P-type GaN layer 16 having the current block layer 78 formed thereon. Subsequently, the same steps as those in FIGS. 5C to 6C are performed, and as a result, the semiconductor light emitting device 77 is formed.

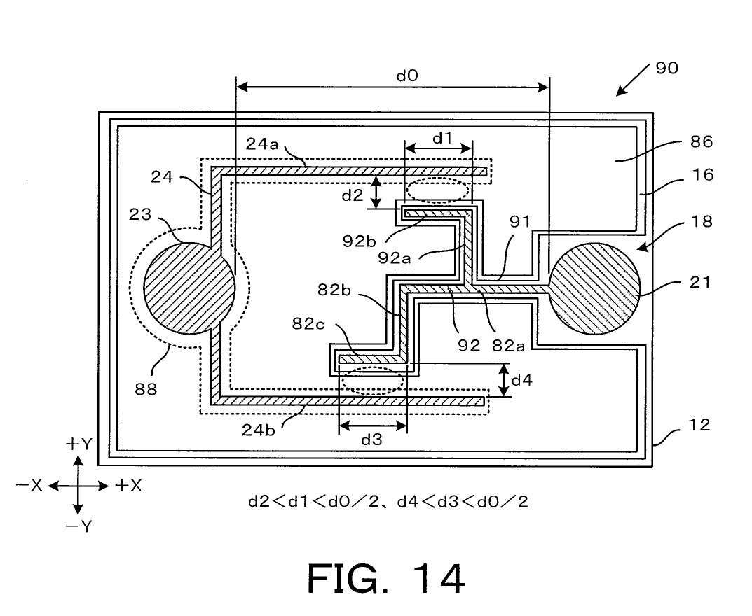

The description of the second embodiment assumes that one stage of first thin wire electrode is provided. Alternatively, multiple stages of first thin wire electrodes may be provided. FIG. 14 is a top view illustrating a semiconductor light emitting device in which multiple stages of first thin wire electrodes are provided.

As shown in FIG. 14, a semiconductor light emitting device 90 includes an indentation unit 91 extending from a cutout unit 18 in −X direction, branching in +Y direction in the middle and further bending in −X direction, as well as branching in −Y direction and further bending −X direction.

A first thin wire electrode 92 is formed from the first pad electrode 21, which is formed on the N-type GaN clad layer 12 in the cutout unit 18, along the indentation unit 91. The first thin wire electrode 92 includes not only a first wire 82a, a second wire 82b, and a third wire 82c but also a sixth wire 92a and a seventh wire 92b. The first wire 82a extends from the first pad electrode 21 in −X direction. The second wire 82b is bent from the first wire 82a in −Y direction. The third wire 82c is bent from the second wire 82b in −X direction. The sixth wire 92a is branched from the middle of the first wire 82a in +Y direction. The seventh wire 92b is bent from the sixth wire 92a in −X direction.

The fourth wire 24a of the second thin wire electrode 24 and the seventh wire 92b of the first thin wire electrode 92 face each other in parallel. The length of the portions facing each other in parallel is d1, and the distance between the portions facing each other in parallel is d2. The semiconductor light emitting device 90 is a structure suitable for a case where the chip size is relatively large.

### Third Embodiment

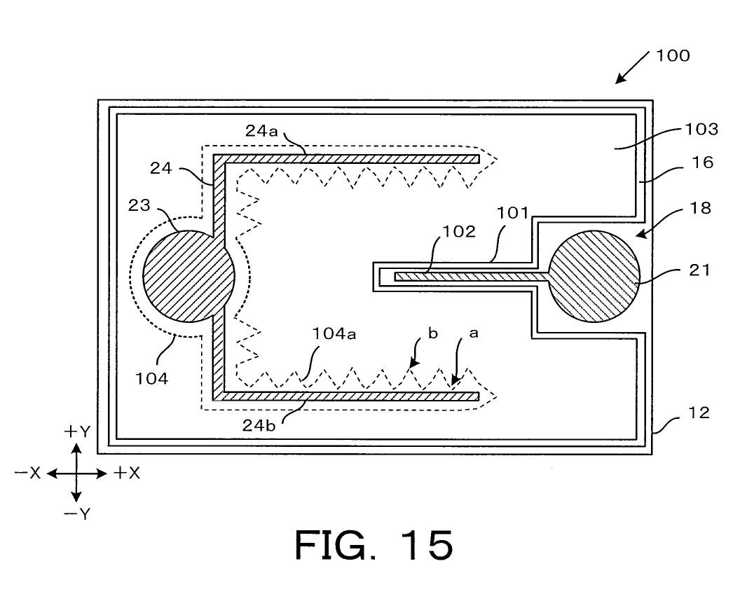

A semiconductor light emitting device of a third embodiment will be described with reference to FIG. 15. FIG. 15 is a top view illustrating the semiconductor light emitting device of the third embodiment. In the third embodiment, the same constituent portions as those of the first embodiment are denoted with the same reference numerals, but the description for the same constituent portions is omitted. Only different portions will be hereinafter described.

The third embodiment is different from the first embodiment in that the distance between a first thin wire electrode and a second thin wire electrode is changed substantially alternately along a second thin wire electrode.

As shown in FIG. 15, a semiconductor light emitting device 100 according to the embodiment has an indentation unit 101 extending from the cutout unit 18 in −X direction. A first thin wire electrode 102 is formed from the first pad electrode 21, formed in the cutout unit 18, along the indentation unit 101.

A transparent conductive film 103 is formed on a P-type GaN layer 16. A current block layer 104, corresponding to the second pad electrode 23 and the second thin wire electrode 24, formed between the P-type GaN contact layer 16 and the transparent conductive film 103.

The current block layer 104 has a sawtooth-shaped depression/protrusion portion 104a formed at the edge facing the first thin wire electrode 102. The distance between the current block layer 104 and the first thin wire electrode 102 is changed alternately in accordance with the depression/protrusion portion 104a.

The distance between a depression portion a of the depression/protrusion portion 104a and the first thin wire electrode 102 is long, and the distance between a protrusion portion b of the depression/protrusion portion 104a and the first thin wire electrode 102 is short. Therefore, the distance between the first thin wire electrode 102 and the second thin wire electrode 24 is changed substantially alternately along the second thin wire electrode 24.

Since the depression portion a of the depression/protrusion portion 104a is close to the second thin wire electrode 24, the carrier density in the depression portion a of the depression/protrusion portion 104a a is high. On the other hand, since the protrusion portion b of the depression/protrusion portion 104a is far away from the second thin wire electrode 24, the carrier density in the protrusion portion b of the depression/protrusion portion 104a is low.

In portions where the carrier density is low, the ratio of the nonradiative recombination increases. However, in portions where the carrier density is high, most of the carriers can be radiatively recombined, and the overall light emission efficiency can be improved. The cycle of the depression/protrusion portion 104a is preferably a value that can be divided by 10 times the diffusion length of the carriers or more (1 to 100 μm).

As described above, in the semiconductor light emitting device 100 according to the embodiment, the sawtooth-shaped depression/protrusion portion 104a is formed at the edge of the current block layer 104 facing the first thin wire electrode 102.

As a result, the carrier density in the depression portion a increases, and the carrier density in the protrusion portion b decreases. Condensation and rarefaction occur in the carrier density, and the overall light emission efficiency can be improved.

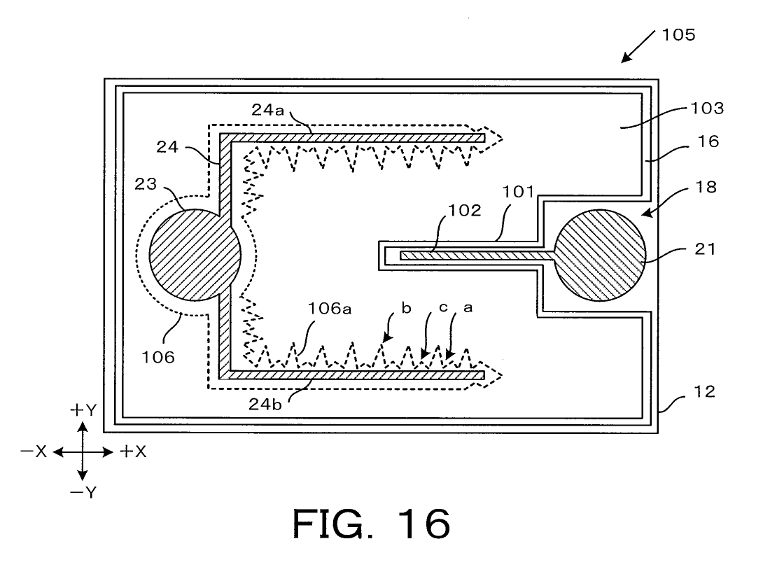

FIG. 16 is a top view illustrating a semiconductor light emitting device in which there are two heights of the sawteeth. As shown in FIG. 16, a semiconductor light emitting device 105 has a sawtooth-shaped depression/protrusion portion 106a at the edge of the current block layer 106 facing the first thin wire electrode 102. The sawtooth-shaped depression/protrusion portion 106a has a protrusion portion c disposed between a depression portion a and a protrusion portion b. The height of the protrusion portion c is less than the height of the protrusion portion b.

With the sawtooth-shaped depression/protrusion portion 106a in which there are two heights of the sawteeth, the points where the carrier density is high are distributed. Therefore, there is an advantage in that the reduction of the light emission efficiency caused by excessive concentration of the current can be suppressed.

The description of the third embodiment assumes that the depression/protrusion portion 104a is in sawtooth shape. However, the same effects can be obtained even when the depression/protrusion portion 104a is in other shapes such as a rectangular wave shape and a wave shape.

### Fourth Embodiment

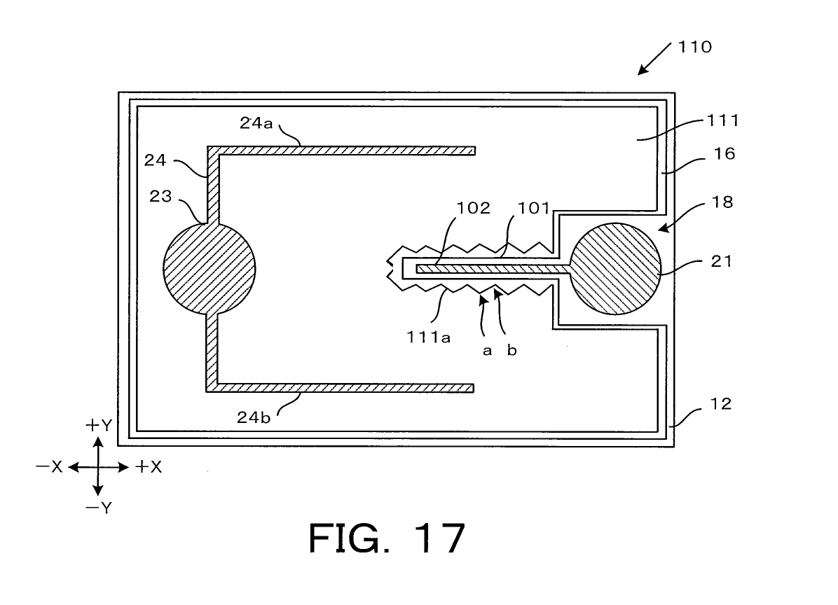

A semiconductor light emitting device of a fourth embodiment will be described with reference to FIG. 17. FIG. 17 is a top view illustrating the semiconductor light emitting device of the fourth embodiment. In the fourth embodiment, the same constituent portions as those of the third embodiment are denoted with the same reference numerals, but the description for the same constituent portions is omitted. Only different portions will be hereinafter described.

The fourth embodiment is different from the third embodiment in that an edge of a transparent conductive film facing a first thin wire electrode has a depression/protrusion portion.

As shown in FIG. 17, in a semiconductor light emitting device 110 of the fourth embodiment, a transparent conductive film 111 has a sawtooth-shaped depression/protrusion portion 111a formed at the edge facing a first thin wire electrode 102. The distance between the transparent conductive film 111 and the first thin wire electrode 102 is changed alternately in accordance with the depression/protrusion portion 111a.

The distance between a depression portion a of the depression/protrusion portion 111a and the first thin wire electrode 102 is long, and the distance between a protrusion portion b of the depression/protrusion portion 111a and the first thin wire electrode 102 is short. Therefore, the distance between the first thin wire electrode 102 and the second thin wire electrode 24 is changed substantially alternately along the second thin wire electrode 24.

When carriers are more likely to move in the transparent conductive film 111 than in the N-type GaN clad layer 12, carriers injected from the second thin wire electrode 24 spread to the protrusion portion b of the end of the transparent conductive film 111, and accordingly, the carrier density increases. On the other hand, in the depression portion a, the carrier density decreases.

When carriers are less likely to move in the transparent conductive film 111 than in the N-type GaN clad layer 12, carriers injected from the first thin wire electrode 102 spread to below the depression portion a of the end of the transparent conductive film 111, and accordingly, the carrier density increases. On the other hand, in the protrusion portion b, the carrier density decreases.

In any case, in portions where the carrier density is low, the ratio of the nonradiative recombination increases. However, in portions where the carrier density is high, most of the carriers can be radiatively recombined, and the overall light emission efficiency can be improved.

The cycle of the depression/protrusion portion 111a is preferably a value that can be divided by 10 times the diffusion length of the carriers or more (1 to 100 μm).

As described above, in the semiconductor light emitting device 110 of the fourth embodiment, the sawtooth-shaped depression/protrusion portion 111a is formed at the edge of the transparent conductive film 111 facing the first thin wire electrode 102.

As a result, the carrier density in the depression portion a increases, and the carrier density in the protrusion portion b decreases. Condensation and rarefaction occur in the carrier density, and the overall light emission efficiency can be improved.

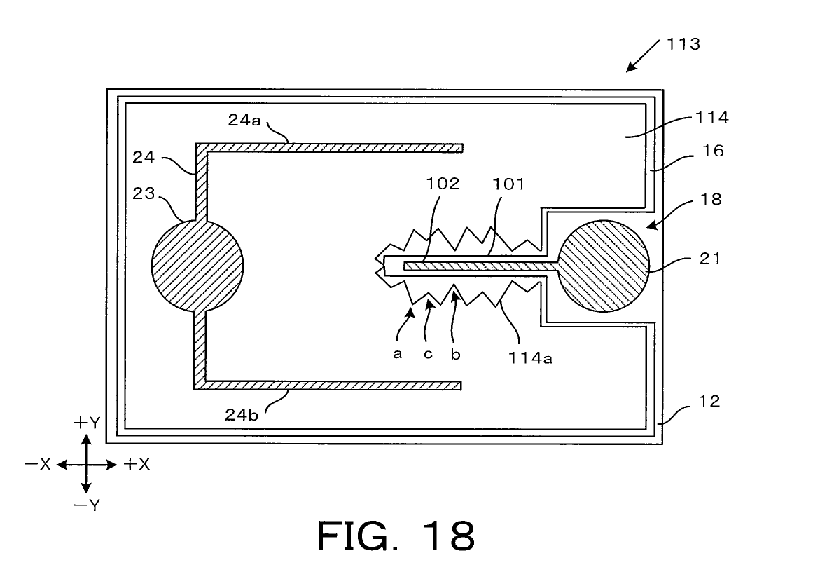

FIG. 18 is a top view illustrating a semiconductor light emitting device in which there are two heights of the sawteeth. As shown in FIG. 18, a semiconductor light emitting device 113 has a sawtooth-shaped depression/protrusion portion 114a at the edge of transparent conductive film 114 facing the first thin wire electrode 102. The sawtooth-shaped depression/protrusion portion 114a has a protrusion portion c disposed between a depression portion a and a protrusion portion b. The height of the protrusion portion c is less than the height of the protrusion portion b.

With the sawtooth-shaped depression/protrusion portion 114a in which there are two heights of the sawteeth, the points where the carrier density is high are distributed. Therefore, there in an advantage in that the reduction of the light emission efficiency caused by excessive concentration of the current can be suppressed.

The description of the fourth embodiment assumes that the depression/protrusion portion 114a is in sawtooth shape. However, the same effects can be obtained even when the depression/protrusion portion 114a is in other shapes such as a rectangular wave shape and a wave shape.

### Fifth Embodiment

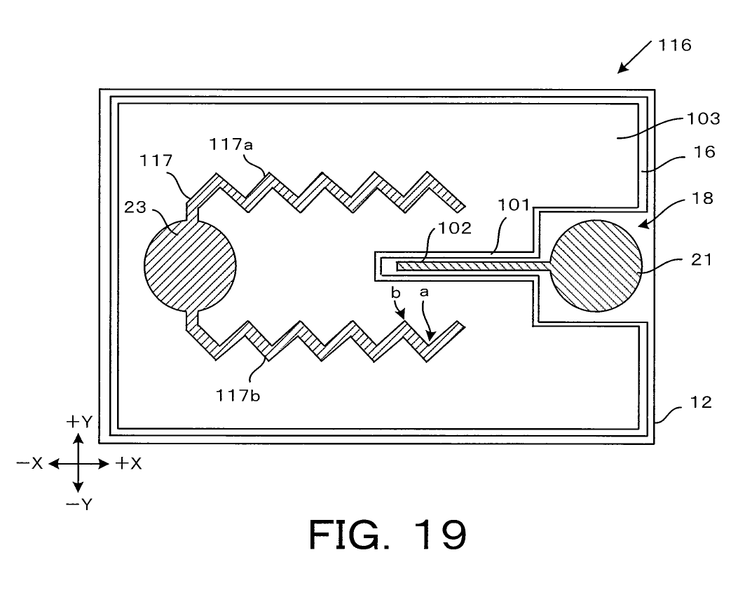

A semiconductor light emitting device of a fifth embodiment will be described with reference to FIG. 19. FIG. 19 is a top view illustrating the semiconductor light emitting device of the fifth embodiment. In the fifth embodiment, the same constituent portions as those of the third embodiment are denoted with the same reference numerals, and the description for the same constituent portions is omitted. Only different portions will be hereinafter described. The fifth embodiment is different from the third embodiment in that the shape of a second thin wire electrode is in a zigzag form.

That is, as shown in FIG. 19, in a semiconductor light emitting device 116 according to the embodiment, a fourth wire 117a of a second thin wire electrode 117 is bent alternately in a zigzag form. The fifth wire 117b of the second thin wire electrode 117 is the same as the fourth wire 117a.

The distance between a depression portion a of the second thin wire electrode 117 and the first thin wire electrode 102 is long, and the distance between a protrusion portion b of the second thin wire electrode 117 and the first thin wire electrode 102 is short. Therefore, the distance between the first thin wire electrode 102 and the second thin wire electrode 117 is changed substantially alternately along the second thin wire electrode 117.

As a result, there are portions where the distance between the second thin wire electrode 117 and the first pad electrode 21/the first thin wire electrode 102 is close and the carrier density is high, and there are portions where the distance between the second thin wire electrode 117 and the first pad electrode 21/the first thin wire electrode 102 is far and the carrier density is low.

In portions where the carrier density is low, the ratio of the nonradiative recombination increases. However, in the portions where the carrier density is high, most of the carriers can be radiatively recombined, and the overall light emission efficiency can be improved.

The cycle of the bend of the second thin wire electrode 117 is preferably a value that can be divided by the diffusion length of the carriers or more (2 to 100 μm).

The description of the fifth embodiment assumes that the second thin wire electrode 117 is in sawtooth shape. However, the same effects can be obtained even when the second thin wire electrode 117 is in other shapes such as a rectangular wave shape and a wave shape.

### Sixth Embodiment

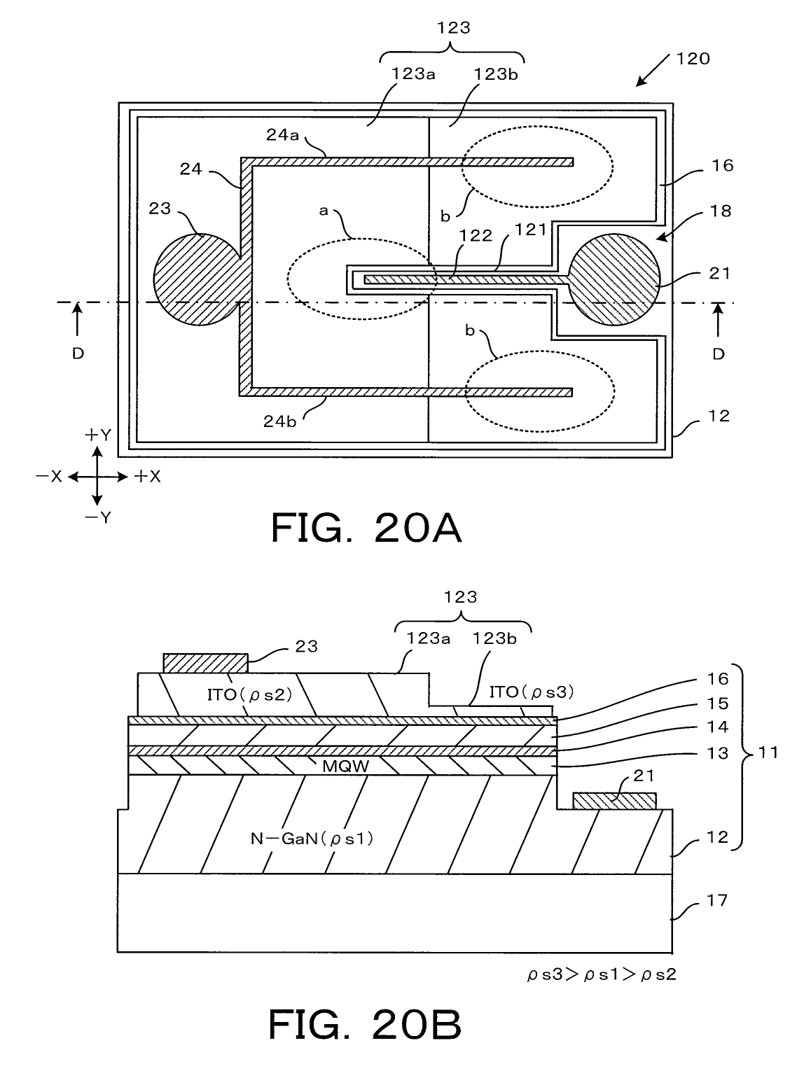

A semiconductor light emitting device of a sixth embodiment will be described with reference to FIGS. 20A to 20B. FIGS. 20A to 20B are views illustrating the semiconductor light emitting device of the sixth embodiment. FIG. 20A is a top view of the semiconductor light emitting device of the sixth embodiment. FIG. 20B is a cross sectional view taken along line D-D of FIG. 20A as seen in an arrow direction.

In the sixth embodiment, the same constituent portions as those of the first embodiment are denoted with the same reference numerals, and the description for the same constituent portions is omitted. Only different portions will be hereinafter described. The sixth embodiment is different from the first embodiment in that a transparent conductive film is formed with a higher sheet resistance region and a lower sheet resistance region as compared with the sheet resistance of the N-type GaN clad layer.

As shown in FIG. 20, a semiconductor light emitting device 120 of the sixth embodiment has an indentation unit 121 extending from a cutout unit 18 in −X direction. A first thin wire electrode 122 is formed from a first pad electrode 21 formed in the cutout unit 18 along the indentation unit 121.

A transparent conductive film 123 is formed on a P-type GaN contact layer 16. The transparent conductive film 123 includes a first region 123a and a second region 123b. The first region 123a has a second sheet resistance ρs2 lower than the first sheet resistance ρs1 of the N-type GaN clad layer 12 from the middle of the indentation unit 121 to the other end side. The second region 123b has a third sheet resistance ρs3 higher than the first sheet resistance ρs1 of the N-type GaN clad layer 12 from the middle of the indentation unit 121 to the one end side.

The first region 123a having the second sheet resistance ρs2 and the second region 123b having the third sheet resistance ρs3 are separately made by changing the thickness of the transparent conductive film 123. The first region 123a is formed to be thicker than the second region 123b.

When the impurity concentration of the N-type GaN clad layer 12 is 2E18 cm⁻³, the N-type GaN clad layer 12 has a mobility of approximately 300 to 400 cm²/V·s and a resistivity of 8E-3 to 1E-2 Ωcm. The resistivity of the transparent conductive film 123 can be approximately 2E-4 Ωcm.

When the thickness of the N-type GaN clad layer 12 is 4 μm, the first sheet resistance ρs1 of the N-type GaN clad layer 12 is 20 to 25Ω/.

On the other hand, when the thickness of the transparent conductive film 123 is 0.17 μm, the transparent conductive film 123 has a sheet resistance of 10Ω/, which is lower than the first sheet resistance ρs1 of the N-type GaN clad layer 12. When the thickness of the transparent conductive film 123 is 0.05 μm, the transparent conductive film 123 has a sheet resistance of 40Ω/, which is higher than the first sheet resistance ρs1 of the N-type GaN clad layer 12.

A second thin wire electrode 24 is formed from the first region 123a of the transparent conductive film 123 to the second region 123b of the transparent conductive film 123.

Therefore, in the first region 123a of the transparent conductive film 123, the holes are likely to spread, and the current is likely to be concentrated on a periphery a of the first thin wire electrode 122. On the other hand, in the second region 123b of the transparent conductive film 123, the holes are less likely to spread, and the current is likely to be concentrated on a periphery b of the second thin wire electrode 24.

As the current is concentrated, condensation and rarefaction occur in the carrier density, and the overall light emission efficiency can be improved. The light emission pattern can also be expanded by providing two or more regions where the current is concentrated to appropriately disperse the current.

In the first region 123a of the transparent conductive film 123, holes move within the transparent conductive film 123. In the second region 123b of the transparent conductive film 123, mainly electrons move within the N-type GaN clad layer 12. Therefore, it is less likely that the resistance becomes excessively high in whole.

It should be noted that a P-type nitride semiconductor has a higher resistivity than that of a transparent conductive film such as ITO, and it is difficult to grow the P-type nitride semiconductor thickly, which results in a high sheet resistance. The current spreads substantially through the transparent conductive film 123. Spread of the current through the P-type layers such as the P-type GaN clad layer 15 and the P-type GaN contact layer 16 can be disregarded.

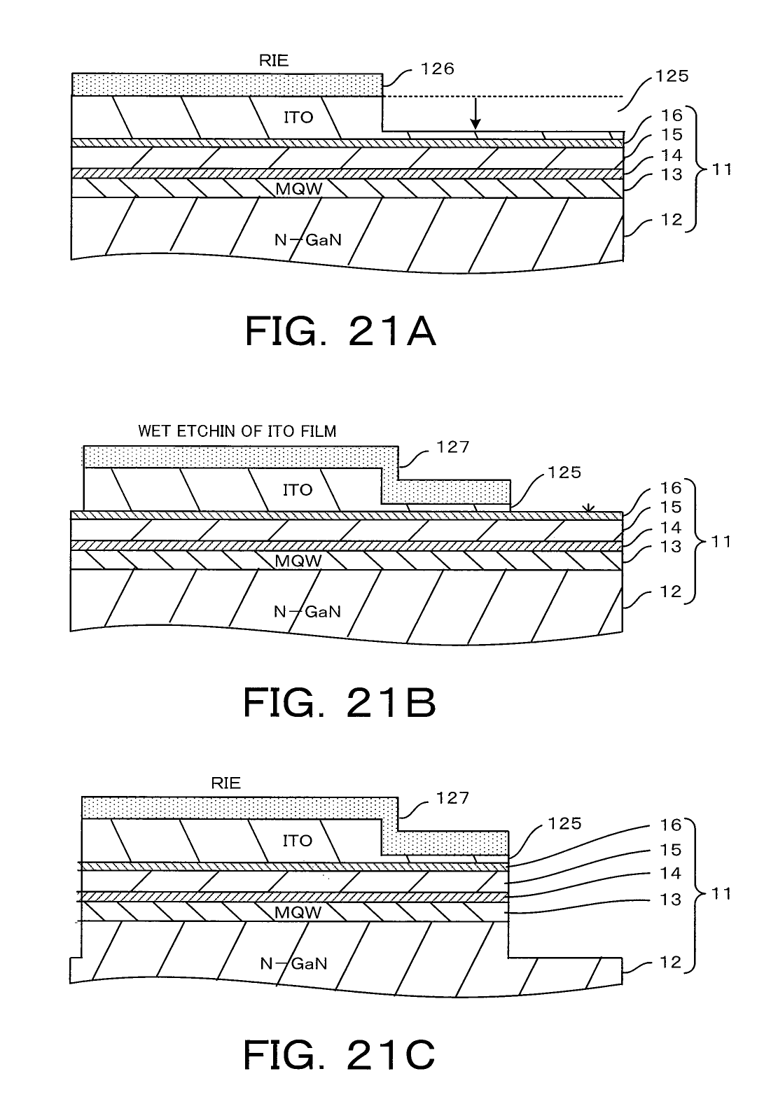

A manufacturing method of the semiconductor light emitting device 120 will be described. FIG. 21 is a cross-sectional view illustrating, in order, main portions of the steps of manufacturing the semiconductor light emitting device 120. Like FIGS. 5A and 5B, the semiconductor laminated body 11 is formed on the substrate 17, and an ITO film 125 of a thickness 200 nm, for example, is formed on the semiconductor laminated body 11.

As shown in FIG. 21A, a resist film 126 having openings corresponding to the second region 123a is formed on the ITO film 125 by photolithographic method. Using the resist film 126 as a mask, the ITO film 125 is anisotropically etched by RIE method, so that the ITO film is thinned down to 50 nm, for example.

As shown in FIG. 21B, after the resist film 126 is removed, a resist film 127 having openings corresponding to the cutout unit 18 and the indentation unit 121 is formed on the ITO film 125 by photolithographic method. A portion of the thinned ITO film 125 is covered with the resist film 127.

Using the resist film 127 as a mask, the ITO film 125 is wet-etched, so that a portion of the P-type GaN contact layer 16 is exposed.

As shown in FIG. 21C, the layers from the P-type GaN contact layer 16 to the upper portion of the N-type GaN clad layer 12 are anisotropically etched using the resist film 127 as the mask by RIE method, and a portion of the N-type GaN clad layer 12 is exposed.

Like FIGS. 6B and 6C, the ITO film 125 is undercut, and subjected to the heat treatment. Subsequently, the first and second pad electrodes 21, 23 and the first and second thin wire electrodes 122, 24 are formed.

As described above, in semiconductor light emitting device 120 of the sixth embodiment, the first region 123a having a second sheet resistance ρs2 lower than the first sheet resistance ρs1 of the N-type GaN clad layer 12 is formed on the transparent conductive film 123, and the second region 123b having a third sheet resistance ρs3 higher than the first sheet resistance ρs1 is formed. The second thin wire electrode 24 is formed from the first region 123a to the second region 123b.

As a result, in the first region 123a, the current is likely to be concentrated on the periphery of the first thin wire electrode 122. In the second region 123b, the current is likely to be concentrated on the periphery of the second thin wire electrode 24.

Condensation and rarefaction is formed in the carrier density. Accordingly, in the portions where the carrier density is low, the ratio of the nonradiative recombination increases. However, in the portions where the carrier density is high, most of the carriers can be radiatively recombined, and the overall light emission efficiency can be improved.

A current block layer corresponding to the second pad electrode 23 and the second thin wire electrode 24 may be formed between the P-type GaN contact layer 16 and the transparent conductive film 123.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

What is claimed is:

1. A semiconductor light emitting device comprising:
a semiconductor laminated body made by laminating, in order, a first semiconductor layer of a first conductivity type having a first sheet resistance, a light emitting layer, and a second semiconductor layer of a second conductivity type, the semiconductor laminated body including a cutout unit formed at an end side so as to expose a portion of the first semiconductor layer, the semiconductor laminated body including an indentation unit extending from the cutout unit in a first direction toward the other end side and branching or bending in a second direction substantially perpendicular to the first direction as well as bending or branching in a direction opposite to the second direction;
a transparent conductive film formed on the semiconductor laminated body, the transparent conductive film having transparency to light emitted from the light emitting layer and having a second sheet resistance less than the first sheet resistance;
a first thin wire electrode formed on the first semiconductor layer, the first thin wire electrode extending from a first pad electrode formed in the cutout unit along the indentation unit; and
a second thin wire electrode formed on the transparent conductive film, the second thin wire electrode extending from a second pad electrode formed at the other end side in the second direction as well as in a direction opposite to the second direction and bending and extending in a direction opposite to the first direction.

2. The semiconductor light emitting device of claim 1, wherein a first distance between portions where the first thin wire electrode and the second thin wire electrode face each other in a substantially perpendicular direction in top view is shorter than a second distance between portions where the first thin wire electrode and the second thin wire electrode face each other in a substantially parallel direction.

3. The semiconductor light emitting device of claim 1, wherein the transparent conductive film is formed inside the edge of the semiconductor laminated body, the distance between the edge of the transparent conductive film and the edge of the semiconductor laminated body is equal to or more than 10 times a diffusion length of minority carriers injected into the light emitting layer.

4. The semiconductor light emitting device of claim 1, wherein the semiconductor laminated body is a nitride semiconductor laminated body.

5. The semiconductor light emitting device of claim 4, wherein the light emitting layer is a Multiple Quantum Well made by alternately laminating Inₓ₁Al_{y1}Ga_{(1-x1-y1)}N well layers (0<x1<1, 0≦y1<1) and Inₓ₂Al_{y2}Ga_{(1-x2-y2)}N (0≦x2<1, 0≦y2<1, x1>x2) barrier layers.

6. A semiconductor light emitting device comprising:
a semiconductor laminated body made by laminating, in order, a first semiconductor layer of a first conductivity type, a light emitting layer, and a second semiconductor layer of a second conductivity type, the semiconductor laminated body including a cutout unit formed at an end side so as to expose a portion of the first semiconductor layer, the semiconductor laminated body including an indentation unit extending from the cutout unit in a first direction toward the other end side, bending in a second direction substantially perpendicular to the first direction, and further bending in the first direction;
a first thin wire electrode including a first wire, a second wire, and a third wire formed on the first semiconductor layer, the first thin wire electrode extending from a first pad electrode formed in the cutout unit along the indentation unit, the first wire extending from the first pad electrode to the first direction, the second wire bending from the first wire in a second direction, and the third wire bending from the second wire in the first direction; and
a second thin wire electrode including fourth and fifth wires formed on the semiconductor laminated body, the second thin wire electrode extending from a second pad electrode formed at the other end side in the second direction as well as in a direction opposite to the second direction and bending and extending in a direction opposite to the first direction so as to sandwich the first thin wire electrode,
wherein where, in a top view, the distance between the first pad electrode and the second pad electrode is denoted as d0, the length of portions where the first wire and the fourth wire face each other is denoted as d1, the distance of portions where the first wire and the fourth wire face each other is denoted as d2, the length of portions where the third wire and the fifth wire face each other is denoted as d3, and the distance between portions where the third wire and the fifth wire face each other is denoted as d4,
the following relationships are satisfied: d2<d1<d0/2, d4<d3<d0/2.

7. The semiconductor light emitting device of claim 6, further comprising:
a transparent conductive film formed on the semiconductor laminated body and having transparency to light emitted from the light emitting layer,
wherein the second pad electrode and the second thin wire electrode are formed on the transparent conductive film.

8. The semiconductor light emitting device of claim 7, further comprising;
An insulating film formed between the semiconductor laminated body and the transparent conductive film corresponding to the second pad electrode and the second thin wire electrode.

9. A semiconductor light emitting device comprising:
a semiconductor laminated body made by laminating, in order, a first semiconductor layer of a first conductivity type, a light emitting layer, and a second semiconductor layer of a second conductivity type, the semiconductor laminated body including a cutout unit formed at an end side so as to expose a portion of the first semiconductor layer, the semiconductor laminated body including an indentation unit extending from the cutout unit in a first direction toward the other end side;
a transparent conductive film formed on the semiconductor laminated body and having transparency to light emitted from the light emitting layer;
a first thin wire electrode formed on the first semiconductor layer, the first thin wire electrode extending from a first pad electrode formed in the cutout unit along the indentation unit; and
a second thin wire electrode formed on the transparent conductive film, the second thin wire electrode extending from a second pad electrode formed at the other end side in the second direction substantially perpendicular to the first direction as well as in a direction opposite to the second direction and bending and extending in a direction opposite to the first direction so as to sandwich the first thin wire electrode,
wherein the distance between the first thin wire electrode and the second thin wire electrode is changed substantially alternately along the second thin wire electrode.

10. The semiconductor light emitting device of claim 9, further comprising;
An insulating film formed between the semiconductor laminated body and the transparent conductive film corresponding to the second pad electrode and the second thin wire electrode,
wherein a depression/protrusion portion is formed at the edge of the insulating film facing the first thin wire electrode.

11. The semiconductor light emitting device of claim 10, wherein the depression/protrusion portion has protrusion portions from which the heights are different.

12. The semiconductor light emitting device of claim 10, wherein the depression/protrusion portion is in a saw-tooth shape, a rectangular wave shape or a wave shape.

13. The semiconductor light emitting device of claim 9, wherein a depression/protrusion portion is formed at the edge of the transparent conductive film facing the first thin wire electrode.

14. The semiconductor light emitting device of claim 13, wherein the depression/protrusion portion has protrusion portions from which the heights are different.

15. The semiconductor light emitting device of claim 13, wherein the depression/protrusion portion is in a saw-tooth shape, a rectangular wave shape or a wave shape.

16. The semiconductor light emitting device of claim 9, wherein the second thin wire electrode has a depression/protrusion portion which is bent alternately.

17. The semiconductor light emitting device of claim 16, wherein the depression/protrusion portion is in a saw-tooth shape, a rectangular wave shape and a wave shape.

18. The semiconductor light emitting device of claim 9, wherein the transparent conductive film is formed inside the edge of the semiconductor laminated body, the distance between the edge of the transparent conductive film and the edge of the semiconductor laminated body is equal to or more than 10 times a diffusion length of minority carriers injected into the light emitting layer.
